(19) United States
(12) Patent Application Publication
(10) Pub. No.: US 2014/0083624 A1
(43) Pub. Date: Mar. 27, 2014

(54) SOLUTION OF AROMATIC POLYAMIDE FOR PRODUCING DISPLAY ELEMENT, OPTICAL ELEMENT, OR ILLUMINATION ELEMENT

(71) Applicants: Frank W. Harris, Boca Raton, FL (US); Dong Zhang, Uniontown, OH (US); Limin Sun, Copley, OH (US); Jiaokai Jing, Uniontown, OH (US); Toshimasa Eguchi, Kobe City (JP); Hideo Umeda, Kobe City (JP); Ritsuya Kawasaki, Kobe City (JP); Toshihiko Katayama, Kobe City (JP); Yusuke Inoue, Kobe City (JP); Jun Okada, Kobe City (JP); Fumihiro Maeda, Fujieda City (JP); Mizuho Inoue, Kobe City (JP); Manabu Naito, Kobe City (JP)

(72) Inventors: Frank W. Harris, Boca Raton, FL (US); Dong Zhang, Uniontown, OH (US); Limin Sun, Copley, OH (US); Jiaokai Jing, Uniontown, OH (US); Toshimasa Eguchi, Kobe City (JP); Hideo Umeda, Kobe City (JP); Ritsuya Kawasaki, Kobe City (JP); Toshihiko Katayama, Kobe City (JP); Yusuke Inoue, Kobe City (JP); Jun Okada, Kobe City (JP); Fumihiro Maeda, Fujieda City (JP); Mizuho Inoue, Kobe City (JP); Manabu Naito, Kobe City (JP)

(73) Assignees: Akron Polymer Systems, Inc., Akron, OH (US); Sumitomo Bakelite Co., Ltd., Shinagawa-ku (JP)

(21) Appl. No.: 14/035,446

(22) Filed: Sep. 24, 2013

Related U.S. Application Data
(60) Provisional application No. 61/704,852, filed on Sep. 24, 2012.

(51) Int. Cl. H01L 51/00; B29D 11/00

(52) U.S. Cl. CPC H01L 51/0097; B29D 11/0073
USPC 156/701; 524/597; 524/233; 427/58

(57) ABSTRACT

The present disclosure is directed toward solutions, transparent films prepared from aromatic copolyamides, and a display element, an optical element or an illumination element using the solutions and/or the films. The copolyamides, which contain pendant carboxylic groups are solution cast into films using cresol, xylene, N,N-dimethylacetamide (DMAc), N-methyl-2-pyrrolidinone (NMP), dimethylsulfoxide (DMSO), or butyl cellosolve or other solvents or mixed solvent which has more than two solvents. When the films are thermally cured at temperatures near the copolymer glass transition temperature, after curing, the polymer films display transmittances >80% from 400 to 750 nm, have coefficients of thermal expansion of less than 20 ppm, and are solvent resistant.

### CROSS-REFERENCE TO RELATED APPLICATION

This application is based upon and claims the benefit of priority under 35 U.S.C. 119 to U.S. provisional patent application 61/704,852, filed Sep. 24, 2012, the entire contents of which are incorporated herein by reference.

### BACKGROUND OF THE INVENTION

1. Field of the Invention

The disclosure, in one aspect, relates to the manufacture of thermally and dimensionally stable transparent polymer films. More particularly, the disclosure, in one aspect, relates to the manufacture and use of aromatic polyamides, which have a rigid backbone with a glass transition temperature higher than 300° C., yet are still soluble in conventional organic solvents without the need for the presence of inorganic salts. The polymer films can be prepared by solution casting, and cured at elevated temperatures. The cured films show a high optical transparency over a range of 400˜750 nm, (transmittance >80%), a low coefficient of thermal expansion (CTE <20 ppm/° C.), and good solvent resistance.

Furthermore, this disclosure, in one aspect, relates to a solution of polyamide including an aromatic copolyamide and a solvent. The aromatic copolyamide in the polyamide solution includes at least two repeat units, and at least one of the repeat units has one or more free carboxylic group. This disclosure, in another aspect, relates to a process of manufacturing the polyamide solution. This disclosure, in another aspect, relates to a process for manufacturing a display element, an optical element or an illumination element, including a step of forming a polyamide film using the polyamide solution.

2. Description of the Background Art

Organic Light Emitting Diode (OLED) displays were a $1.25 billion market in 2010, which is projected to grow annually at a rate of 25%. The high efficiency and high contrast ratio of OLED displays make them a suitable replacement for liquid crystal displays (LCDs) in the mobile phone display, digital camera, and global positioning system (GPS) market segments. These applications place a premium on high electrical efficiency, compact size, and robustness. This has increased the demand for active matrix OLEDs (AMOLEDs) which consume less power, have faster response times, and higher resolutions. AMOLED innovations that improve these properties will further accelerate AMOLED adoption into portable devices and expand the range of devices that use them. These performance factors are largely driven by the processing temperature of the electronics. AMOLEDs have a thin-film transistor (TFT) array structure which is deposited on the transparent substrate. Higher TFT deposition temperatures can dramatically improve the electrical efficiency of the display. Currently, glass plates are used as AMOLED substrates. They offer high processing temperatures (>500° C.) and good barrier properties, but are relatively thick, heavy, rigid, and are vulnerable to breaking, which reduces product design freedom and display robustness. Thus, there is a demand by portable device manufacturers for a lighter, thinner, and more robust replacement. Flexible substrate materials would also open new possibilities for product design, and enable lower cost roll-to-roll fabrication.

Many polymer thin films have excellent flexibility, transparency, are relatively inexpensive, and are lightweight. Polymer films are excellent candidates for substrates for flexible electronic devices, including flexible displays and flexible solar cell panels, which are currently under development. Compared to rigid substrates like glass, flexible substrates offer some potentially significant advantages in electronic devices, including:

a. Light weight (glass substrates represent about 98% of the total weight in a thin film solar cell).

b. Flexible (Easy to handle, low transportation costs, and/or more applications for both raw materials and products.)

c. Amenable to roll-to-roll manufacturing, which could greatly reduce the manufacturing costs.

To facilitate these inherent advantages of a polymeric substrate for the flexible display application, several issues must be addressed including:

a. Increasing the thermal stability;

b. Reducing the coefficient of thermal expansion (CTE);

c. Maintaining high transparency during high temperature processing; and,

d. Increasing the oxygen and moisture barrier properties. Currently, no pure polymer film can provide sufficient barrier properties. To achieve the target barrier property, an additional barrier layer must be applied.

Several polymer films have been evaluated as transparent flexible substrates, including: polyethylene terephthalate (PET), polyethylene naphthalate (PEN), polycarbonate (PC), polyethersulfone (PES), cyclic olefin polymer (COP), polyarylates (PAR), polyimides (PI), and others. However, no one film can meet all the requirements. Currently, the industrial standard for this application is PEN film, which meets part of the requirements (Transmittance >80% between 400 nm˜750 nm, CTE <20 ppm/° C.), but has a limited use temperature (<200° C.). A transparent polymer film with a higher thermal stability (T_{g}>300° C.) and a lower CTE (<20 ppm/° C.) is desirable.

Conventional aromatic polyimides are well known for their excellent thermal and mechanical properties, but their films, which must be cast from their polyamic acid precursors, are usually dark yellow to orange. Some aromatic polyimides have been prepared that can be solution cast into films that are colorless in the visible region, but such films do not display the required low CTE (For example, F. Li. F. W. Harris, and S. Z. D. Cheng, Polymer, 37, 23, pp 5321 1996). The films are also not solvent resistant. Polyimide films based on part or all alicyclic monomers, such as those described in patents JP 2007-063417 and JP 2007-231224, and publication by A. S. Mathews et al (J. Appl. Polym. Sci., Vol. 102, 3316-3326, 2006), show improved transparency. Although T_{g}s of these polymers can be higher than 300° C., at these temperatures the polymers do not show sufficient thermal stability due to their aliphatic units.

Although most aromatic polyamides are poorly soluble in organic solvents and cannot be solution cast into films, a few polymers have been prepared that are soluble in polar aprotic solvents containing inorganic salts. Some of these have been investigated for use as flexible substrates. For example, JP 2009-79210A describes a thin film prepared from a fluorine containing aromatic polyamide that displays a very low CTE (<0 ppm/° C.), good transparency (T %>80 between 450˜700 nm), and excellent mechanical properties. However, the maximum thickness of films made from this polymer is 20 μm, because a dry-wet method where the salt is removed must be used for the film preparation. Most importantly, the film also displays poor resistance to strong organic solvents. International Application Number PCT/US2012/030158 (WO2012/129422) is entitled Aromatic Polyamide Films for Transparent Flexible Substrates, filed Mar. 22, 2012, the contents of which are incorporated herein by reference.

### SUMMARY OF THE INVENTION

According to one aspect of the present invention, a solution of polyamide includes an aromatic copolyamide and a solvent. The aromatic copolyamide includes at least two repeat units, and at least one of the repeat units has one or more free carboxylic acid group, and the amount of carboxylic acid containing repeat unit(s) are greater than approximately 1 mole percent and less than approximately 30 mole percent of the total repeat units.

According to another aspect of the present invention, a solution of polyamide includes an aromatic copolyamide and a solvent. The aromatic copolyamide includes at least two repeat units of general formulas (I) and (II):

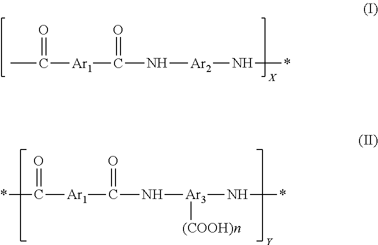

where n=1 to 4, the ratio of X and Y is selected so that the copolyamide is soluble in polar aprotic solvents, Ar₁ is selected from the group including:

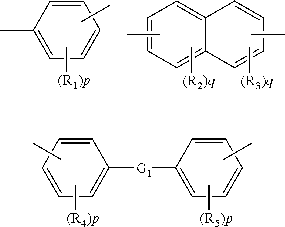

where p=4, q=3, R₁, R₂, R₃, R₄, R₅ are selected from the group including hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, G₁ is selected from the group including a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, such as phenyl group, biphenyl group, perfluorobiphenyl group, 9,9-bisphenylfluorene group, and substituted 9,9-bisphenylfluorene, Ar₂ is selected from the group including:

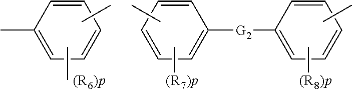

where p=4, R₆, R₇, R₈ are selected from the group including hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, G₂ is selected from the group including a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, such as phenyl group, biphenyl group, perfluorobiphenyl group, 9,9-bisphenylfluorene group, and substituted 9,9-bisphenylflorene, Ar₃ is selected from the group including:

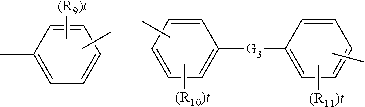

where m=1 or 2, t=1 to 3, R₉, R₁₀, R₁₁ are selected from the group including hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, G₃ is selected from the group including a covalent bond, a CH₂ group, a C(CH₃)₂ group, a C(CF₃)₂ group, a C(CX₃)₂ group, where X is a halogen, a CO group, an O atom, a S atom, a SO₂ group, a Si(CH₃)₂ group, 9,9-fluorene group, substituted 9,9-fluorene, and an OZO group, where Z is a aryl group or substituted aryl group, such as phenyl group, biphenyl group, perfluorobiphenyl group, 9,9-bisphenylfluorene group, and substituted 9,9-bisphenylfluorene.

According to yet another aspect of the present invention, a process for manufacturing a solution of an aromatic copolyamide includes a) forming a mixture of two or more aromatic diamines where at least one of the diamines contains one or more free carboxylic acid groups, such that the amount of carboxylic acid containing diamine is greater than approximately 1 mole percent and less than approximately 30 mole percent of the total diamine mixture, b) dissolving the aromatic diamine mixture in a solvent, c) reacting the diamine mixture with at least one aromatic diacid dichloride, where hydrochloric acid and a polyamide solution is generated, and d) eliminating the hydrochloric acid with a reagent.

According to still another aspect of the present invention, a process for manufacturing a solution of an aromatic copolyamide includes reacting a mixture of aromatic diamines with at least one aromatic diacid chloride in a solvent to form a polyamide wherein a carboxyl group is incorporated along the polyamide backbone, where at least one of the diamines includes a pendant carboxylic acid group of the general formula (III):

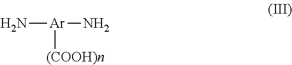

where n=1 to 4, Ar is selected from the group including:

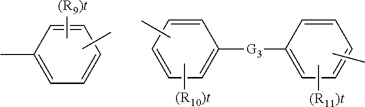

where t=1 to 3, R₉, R₁₀, R₁₁ are selected from the group including hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, G₃ is selected from the group including a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, such as phenyl group, biphenyl group, perfluorobiphenyl group, 9,9-bisphenylfluorene group, and substituted 9,9-bisphenylflorene.

According to still another aspect of the present invention, a process for manufacturing a display element, an optical element or an illumination element includes a) forming a mixture of two or more aromatic diamines where at least one of the diamines contains one or more free carboxylic acid groups, such that the amount of carboxylic acid containing diamine is greater than approximately 1 mole percent and less than approximately 30 mole percent of the total diamine mixture, b) dissolving the aromatic diamine mixture in a solvent, c) reacting the diamine mixture with at least one aromatic diacid dichloride, where hydrochloric acid and a polyamide solution is generated; d) eliminating the hydrochloric acid with a reagent to obtain an aromatic copolyamide solution, e) applying a solution of an aromatic copolyamide onto a base, f) forming a polyamide film on the base after the applying step (e), and g) forming the display element, the optical element or the illumination element on the surface of the polyamide film.

According to still another aspect of the present invention, a process for manufacturing a display element, an optical element or an illumination element includes A) applying a solution of an aromatic copolyamide onto a base, B) forming a polyamide film on the base after the applying step (a), and C) forming the display element, the optical element or the illumination element on the surface of polyamide film. The solution of an aromatic copolyamide comprising an aromatic copolyamide and a solvent, the aromatic copolyamide includes at least two repeat units of general formulas (I) and (II):

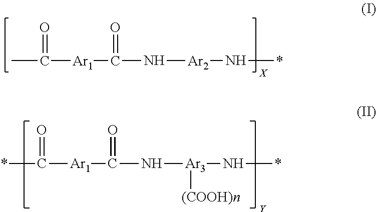

where n=1 to 4, Ar₁ is selected from the group including:

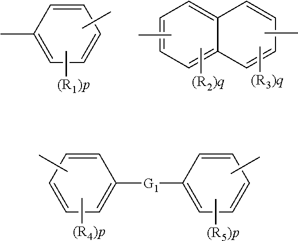

where p=4, q=3, R₁, R₂, R₃, R₄, R₅ are selected from the group including hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof, G₁ is selected from the group including a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, such as phenyl group, biphenyl group, perfluorobiphenyl group, 9,9-bisphenylfluorene group, and substituted 9,9-bisphenylfluorene, Ar₂ is selected from the group including:

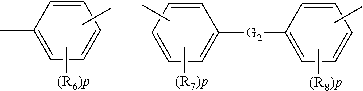

where p=4, R₆, R₇, R₈ are selected from the group including hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, G₂ is selected from the group including a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, such as phenyl group, biphenyl group, perfluorobiphenyl group, 9,9-bisphenylfluorene group, and substituted 9,9-bisphenylflorene, Ar₃ is selected from the group including:

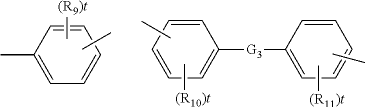

where t=1 to 3, R₉, R₁₀, R₁₁ are selected from the group including hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof, G₃ is selected from the group including a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, such as phenyl group, biphenyl group, perfluorobiphenyl group, 9,9-bisphenylfluorene group, and substituted 9,9-bisphenylfluorene.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a schematic cross-sectional view showing an organic EL element 1 according to one embodiment.

### DETAILED DESCRIPTION OF EMBODIMENTS

The embodiments will now be described with reference to the accompanying drawings, wherein like reference numerals designate corresponding or identical elements throughout the various drawings.

The present disclosure is directed toward solutions, transparent films prepared from aromatic copolyamides, and a display element, an optical element or an illumination element using the solutions and/or the films. A polyamide is prepared via a condensation polymerization in a solvent, where the hydrochloric acid generated in the reaction is trapped by a reagent like propylene oxide (PrO). The film can be made directly from the reaction mixture, without the need for isolating and re-dissolving the polyamide. Colorless films can be prepared by casting procedures directly from the polymerization solutions. The product of the reaction of the hydrochloric acid with the PrO is eliminated during the removal of the solvent. These films display low CTEs as cast and do not need to be subjected to stretching. By carefully manipulating the ratio of the monomers used to prepare the copolyamides, the CTEs and T_{g}s of the resulting copolymers and the optical properties of their solution cast films can be controlled. It is particularly surprising that a film can be cured at an elevated temperature when free carboxylic acid side groups exist along the polymer chains. If the reaction of the reagent with the hydrochloric acid does not form volatile products, the polymer is isolated from the polymerization mixture by precipitation and re-dissolved by a polar solvent (without the need for inorganic salts) and cast in the film. If the reaction of the reagent with the hydrochloric acid does form volatile products, the film can be directly cast. One example, above, of a reagent that forms volatile products is PrO.

Representative and illustrative examples of the useful aromatic diacid dichlorides in the disclosure are:

Terephthaloyl dichloride (TPC);

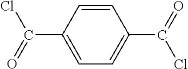 [SMILES: O=C(Cl)c1ccc(C(=O)Cl)cc1]

Isophthaloyl dichloride (IPC);

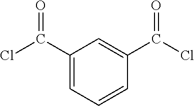 [SMILES: O=C(Cl)c1cccc(C(=O)Cl)c1]

2,6-Naphthaloyl dichloride (NDC);

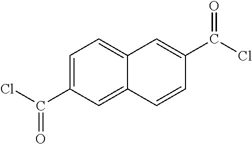 [SMILES: O=C(Cl)c1ccc2cc(C(=O)Cl)ccc2c1]

4,4′-Biphenyldicarbonyl dichloride (BPDC)

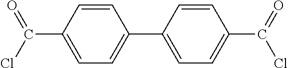 [SMILES: O=C(Cl)c1ccc(-c2ccc(C(=O)Cl)cc2)cc1]

Representative and illustrative examples of the useful aromatic diamines in the disclosure are:

4,4′-Diamino-2,2′-bistrifluoromethylbenzidine (PFMB)

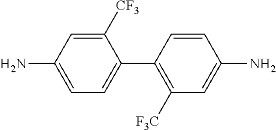 [SMILES: Nc1ccc(-c2ccc(N)cc2C(F)(F)F)c(C(F)(F)F)c1]

9,9-Bis(4-aminophenyl)fluorine (FDA)

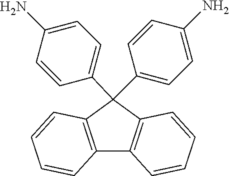 [SMILES: Nc1ccc(C2(c3ccc(N)cc3)c3ccccc3-c3ccccc32)cc1]

9,9-Bis(3-fluoro-4-aminophenyl)fluorine (FFDA)

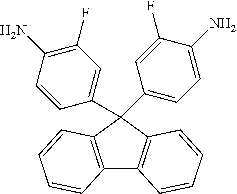 [SMILES: Nc1ccc(C2(c3ccc(N)c(F)c3)c3ccccc3-c3ccccc32)cc1F]

4,4′-Diaminodiphenic acid (DADP)

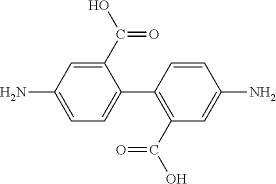 [SMILES: Nc1ccc(-c2ccc(N)cc2C(=O)O)c(C(=O)O)c1]

3,5-Diaminobenzoic acid (DAB)

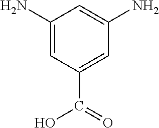 [SMILES: Nc1cc(N)cc(C(=O)O)c1]

4,4′-Diamino-2,2′-bistrifluoromethoxylbenzidine (PFMOB)

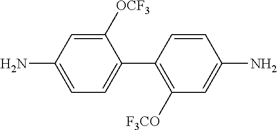 [SMILES: Nc1ccc(-c2ccc(N)cc2OC(F)(F)F)c(OC(F)(F)F)c1]

4,4′-Diamino-2,2′-bistrifluoromethyldiphenyl ether (6FODA)

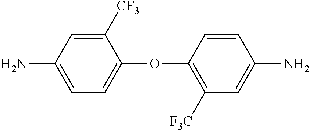 [SMILES: Nc1ccc(Oc2ccc(N)cc2C(F)(F)F)c(C(F)(F)F)c1]

Bis(4-amino-2-trifluoromethylphenyloxyl) benzene (6FOQDA)

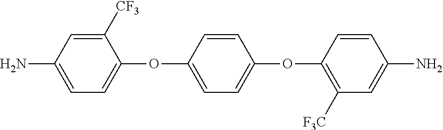 [SMILES: Nc1ccc(Oc2ccc(Oc3ccc(N)cc3C(F)(F)F)cc2)c(C(F)(F)F)c1]

Bis(4-amino-2-trifluoromethylphenyloxyl) biphenyl (6FOBDA)

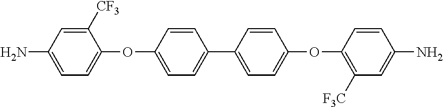 [SMILES: Nc1ccc(Oc2ccc(-c3ccc(Oc4ccc(N)cc4C(F)(F)F)cc3)cc2)c(C(F)(F)F)c1]

### Display Element, Optical Element, or Illumination Element

The term “a display element, an optical element, or an illumination element” as used herein refers to an element that constitutes a display (display device), an optical device, or an illumination device, and examples of such elements include an organic EL element, a liquid crystal element, and organic EL illumination. Further, the term also covers a component of such elements, such as a thin film transistor (TFT) element, a color filter element or the like. In one or more embodiments, the display element, the optical element or the illumination element according to the present disclosure may include the polyamide film according to the present disclosure, may be produced using the solution of polyamide according to the present disclosure, or may use the polyamide film according to the present disclosure as the substrate of the display element, the optical element or the illumination element.

### Non-Limiting Embodiment of Organic EL Element

Hereinafter, one embodiment of an organic EL element as one embodiment of the display element according to the present disclosure will be described with reference to the drawing.

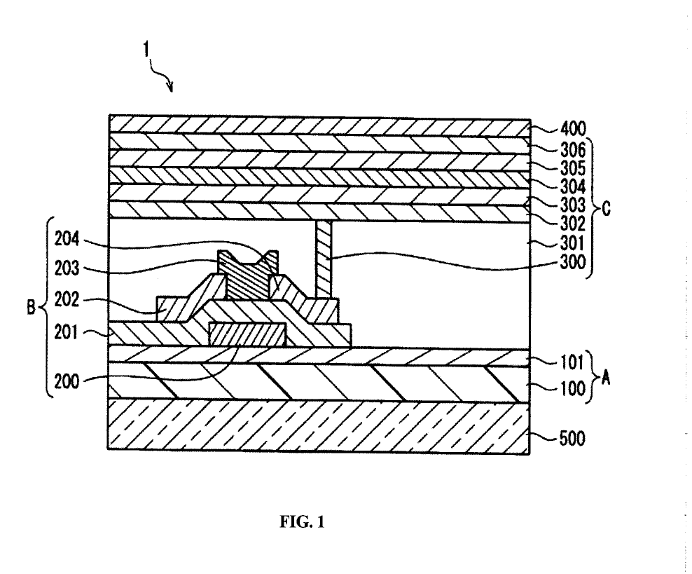

FIG. 1 is a schematic cross-sectional view showing an organic EL element 1 according to one embodiment. The organic EL element 1 includes a thin film transistor B formed on a substrate A and an organic EL layer C. Note that the organic EL element 1 is entirely covered with a sealing member 400. The organic EL element 1 may be separate from a base 500 or may include the base 500. Hereinafter, each component will be described in detail.

### 1. Substrate A

The substrate A includes a transparent resin substrate 100 and a gas barrier layer 101 formed on top of the transparent resin substrate 100. Here, the transparent resin substrate 100 is the polyamide film according to the present disclosure.

The transparent resin substrate 100 may have been annealed by heat. Annealing is effective in, for example, removing distortions and in improving the size stability against environmental changes.

The gas barrier layer 101 is a thin film made of SiOx, SiNx or the like, and is formed by a vacuum deposition method such as sputtering, CVD, vacuum deposition or the like. Generally, the gas barrier layer 101 has a thickness of but is not limited to, about 10 nm to 100 nm. Here, the gas barrier layer 101 may be formed on the side of the transparent resin substrate 100 facing the gas barrier layer 101 in FIG. 1 or may be formed on the both sides of the transparent resin substrate 100.

### 2. Thin Film Transistor

The thin film transistor B includes a gate electrode 200, a gate insulating layer 201, a source electrode 202, an active layer 203, and a drain electrode 204. The thin film transistor B is formed on the gas barrier layer 101.

The gate electrode 200, the source electrode 202, and the drain electrode 204 are transparent thin films made of indium tin oxide (ITO), indium zinc oxide (IZO), zinc oxide (ZnO), or the like. For example, sputtering, vapor deposition, ion platting or the like may be use to form these transparent thin films. Generally, these electrodes have a film thickness of but is not limited to, about 50 nm to 200 nm.

The gate insulating film 201 is a transparent insulating thin film made of SiO₂, Al₂O₃ or the like, and is formed by sputtering, CVD, vacuum deposition, ion plating or the like. Generally, the gate insulating film 201 has a film thickness of, but is not limited to, about 10 nm to 1 μm.

The active layer 203 is a layer of, for example, single crystal silicon, low temperature polysilicon, amorphous silicon, or oxide semiconductor, and a material best suited to the active layer 203 is used as appropriate. The active layer is formed by sputtering or the like.

3. Organic EL layer

The organic EL layer C includes a conductive connector 300, an insulative flattened layer 301, a lower electrode 302 as the anode of the organic EL element A, a hole transport layer 303, a light-emitting layer 304, an electron transport layer 305, and an upper electrode 306 as the cathode of the organic EL element A. The organic EL layer C is formed at least on the gas barrier layer 101 or on the thin film transistor B, and the lower electrode 302 and the drain electrode 204 of the thin film transistor B are connected to each other electrically through the connector 300. Instead, the lower electrode 302 of the thin film transistor B and the source electrode 202 may be connected to each other through the connector 300.

The lower electrode 302 is the anode of the organic EL element 1a, and is a transparent thin film made of indium tin oxide (ITO), indium zinc oxide (IZO), zinc oxide (ZnO) or the like. ITO is preferred because, for example, high transparency, and high conductivity can be achieved.

For the hole transport layer 303, the light-emitting layer 304, and the electron transport layer 305, conventionally-known materials for organic EL elements can be used as is.

The upper electrode 305 is a film composed of a layer of lithium fluoride (LiF) having a film thickness of 5 nm to 20 nm and a layer of aluminum (Al) having a film thickness of 50 nm to 200 nm. For example, vapor deposition may be use to form the film.

When producing a bottom emission type organic EL element, the upper electrode 306 of the organic EL element 1a may be configured to have optical reflectivity. Thereby, the upper electrode 306 can reflect in the display side direction light generated by the organic EL element A and traveled toward the upper side as the opposite direction to the display side. Since the reflected light is also utilized for a display purpose, the emission efficiency of the organic EL element can be improved.

### Method of Producing Display Element, Optical Element, or Illumination Element

Another aspect of the present disclosure relates to a method of producing a display element, an optical element, or an illumination element. In one or more embodiments, the production method according to the present disclosure is a method of producing the display element, the optical element, or the illumination element according to the present disclosure. Further, in one or more embodiments, the production method according to the present disclosure is a method of producing a display element, an optical element, or an illumination element, which includes the steps of: applying the polyamide resin composition according to the present disclosure onto a base; forming a polyamide film after the application step; and forming the display element, the optical element, or the illumination element on the side of the base not in contact with the polyamide resin film. The production method according to the present disclosure may further include the step of de-bonding, from the base, the display element, the optical element, or the illumination element formed on the base.

### Non-Limiting Embodiment of Method of Producing Organic EL Element

As one embodiment of the method of producing a display element according to the present disclosure, hereinafter, one embodiment of a method of producing an organic EL element will be described with reference to the drawing.

A method of producing the organic EL element 1 shown in FIG. 1 includes a fixing step, a gas barrier layer preparation step, a thin film transistor preparation step, an organic EL layer preparation step, a sealing step and a de-bonding step. Hereinafter, each step will be described in detail.

### 1. Fixing Step

In the fixing step, the transparent resin substrate 100 is fixed onto the base 500. A way to fix the transparent resin substrate 100 to the base 500 is not particularly limited. For example, an adhesive may be applied between the base 500 and the transparent substrate or a part of the transparent resin substrate 100 may be fused and attached to the base 500 to fix the transparent resin substrate 100 to the base 500. Further, as the material of the base, glass, metal, silicon, resin or the like is used, for example. These materials may be used alone or in combination of two or more as appropriate. Furthermore, the transparent resin substrate 100 may be attached to the base 500 by applying a releasing agent or the like to the base 500 and placing the transparent resin substrate 100 on the applied releasing agent. In one or more embodiments, the polyamide film 100 is formed by applying the polyamide resin composition according to the present disclosure to the base 500, and drying the applied polyamide resin composition.

### 2. Gas Barrier Layer Preparation Step

In the gas barrier layer preparation step, the gas barrier layer 101 is prepared on the transparent resin substrate 100. A way to prepare the gas barrier layer 101 is not particularly limited, and a known method can be used.

### 3. Thin Film Transistor Preparation Step

In the thin film transistor preparation step, the thin film transistor B is prepared on the gas barrier layer. A way to prepare the thin film transistor B is not particularly limited, and a known method can be used.

### 4. Organic EL Layer Preparation Step

The organic EL layer preparation step includes a first step and a second step. In the first step, the flattened layer 301 is formed. The flattened layer 301 can be formed by, for example, spin-coating, slit-coating, or ink-jetting a photosensitive transparent resin. At that time, an opening needs to be formed in the flattened layer 301 so that the connector 300 can be formed in the second step. Generally, the flattened layer has a film thickness of, but is not limited to, about 100 nm to 2 μm.

In the second step, first, the connector 300 and the lower electrode 302 are formed at the same time. Sputtering, vapor deposition, ion platting or the like may be used to form the connector 300 and the lower electrode 302. Generally, these electrodes have a film thickness of, but is not limited to, about 50 nm to 200 nm. Subsequently, the hole transport layer 303, the light-emitting layer 304, the electron transport layer 305, and the upper electrode 306 as the cathode of the organic EL element A are formed. To form these components, a method such as vapor deposition, application, or the like can be used as appropriate in accordance with the materials to be used and the laminate structure. Further, irrespective of the explanations given in this example, other layers may be chosen from known organic layers such as a hole injection layer, an electron transport layer, a hole blocking layer and an electron blocking layer as needed and be used to configuring the organic layers of the organic EL element A.

### 5. Sealing Step

In the sealing step, the organic EL layer A is sealed with the sealing member 307 from top of the upper electrode 306. For example, a glass material, a resin material, a ceramics material, a metal material, a metal compound or a composite thereof can be used to form the sealing member 307, and a material best suited to the sealing member 307 can be chosen as appropriate.

### 6. De-Bonding Step

In the de-bonding step, the organic EL element 1 prepared is stripped from the base 500. To implement the de-bonding step, for example, the organic EL element 1 may be physically stripped from the base 500. At that time, the base 500 may be provided with a de-bonding layer, or a wire may be inserted between the base 500 and the display element to remove the organic EL element. Further, examples of other methods of de-bonding the organic EL element 1 from the base 500 include the following: forming a de-bonding layer on the base 500 except at ends, and cutting, after the preparation of the element, the inner part from the ends to remove the element from the base; providing a layer of silicon or the like between the base 500 and the element, and irradiating the silicon layer with a laser to strip the element; applying heat to the base 500 to separate the base 500 and the transparent substrate from each other; and removing the base 500 using a solvent. These methods may be used alone or any of these methods may be used in combination of two or more.

In one or more embodiments, the organic EL element obtained by the method of producing a display, optical or illumination element according to the present embodiment has excellent characteristics such as excellent transparency and heat-resistance, low linear expansivity and low optical anisotropy.

### Display Device, Optical Device, and Illumination Device

Another aspect of the present disclosure relates to a display device, an optical device, or an illumination device using the display element, the optical element, or the illumination element according to the present disclosure, or a method of producing the display device, the optical device, or the illumination device. Examples of the display device include, but are not limited to, an imaging element, examples of the optical device include, but are not limited to, a photoelectric complex circuit, and examples of the illumination device include, but are not limited to, a TFT-LCD and OEL illumination.

### EXAMPLES

### Example 1

This example illustrates the general procedure for the preparation of a copolymer from TPC, IPC and PFMB (70%/30%/100% mol) via solution condensation.

To a 250 ml, three necked, round bottom flask, equipped with a mechanical stirrer, a nitrogen inlet and an outlet, are added PFMB (3.2024 g, 0.01 mol) and dried DMAc (45 ml). After the PFMB dissolves completely, IPC (0.6395 g 0.003 mol) is added to the solution at room temperature under nitrogen, and the flask wall is washed with DMAc (1.5 ml). After 15 minutes, TPC (1.4211 g, 0.007 is added to the solution, and the flask wall is again washed with DMAc (1.5 ml). The viscosity of the solution increases until the mixture forms a gel. After adding PrO (1.4 g, 0.024 mol), the gel is broken up under stirring to form a viscous, homogenous solution. After stirring at room temperature for another 4 hours, the resulting copolymer solution can be directly cast into film.

### Example 2

This Example illustrates the general procedure for the preparation of a copolymer from TPC, PFMB, and FDA (100%180%120% mol) via solution condensation. To a 100 ml, four necked, round bottom flask, equipped with a mechanical stirrer, a nitrogen inlet and outlet, are added PFMB (1.0247 g, 3.2 mmol), FDA (0.02788 g, 0.8 mmol), and dried DMAc (20 ml) at room temperature under nitrogen. After the PFMB dissolves completely, TPC (0.8201 g 4.04 mmol) is added to the solution, and the flask wall is washed with DMAc (5.0 ml). The viscosity of the solution increases until the mixture forms a gel. After adding PrO (0.5 g, 8.5 mmol), the gel is broken up under stirring to form a viscous, homogenous solution. After stirring for another 4 hours at room temperature, the resulting copolymer solution can be directly cast into film.

### Example 3

This Example illustrates the general procedure for the preparation of a copolymer from TPC, IPC, DADP, and PFMB (70%/30%/3%/97% mol) via solution condensation.

To a 250 ml, three necked, round bottom flask, equipped with a mechanical stirrer, a nitrogen inlet and outlet, are added PFMB (3.1060 g, 0.0097 mol), DADP (0.0817 g, 0.0003 mol), and dried DMAc (45 ml) at room temperature under nitrogen. After the PFMB dissolves completely, IPC (0.6091 g 0.003 mol) is added to the solution, and the flask wall is washed with DMAc (1.5 ml). After 15 minutes, TPC (1.4211 g, 0.007 mol) is added, and the flask wall is again washed with DMAc (1.5 ml). The viscosity of the solution increases until the mixture forms a gel. After adding PrO (1.4 g, 0.024 mol), the gel is broken up under stirring to form a viscous, homogenous solution. After stirring for another 4 hours at room temperature, the resulting copolymer solution can be directly cast into film.

### Example 4

This Example illustrates the general procedure for the preparation of a copolymer from TPC, IPC, DAB, and PFMB (75%/25%/5%/95% mol) via solution condensation.

To a 250 ml, three necked, round bottom flask, equipped with a mechanical stirrer, a nitrogen inlet and outlet, are added PFMB (3.0423 g, 0.0095 mol), DAB (0.0761 g, 0.0005 mol), and dried DMAc (45 ml) at room temperature under nitrogen. After the PFMB dissolves completely, IPC (0.5076 g 0.0025 mol) is added to the solution, and the flask wall is washed with DMAc (1.5 ml). After 15 minutes, TPC (1.5227 g, 0.0075 mol) is added, and the flask wall is again washed with DMAc (1.5 ml). The viscosity of the solution increases until the mixture forms a gel. After adding PrO (1.4 g, 0.024 mol), the gel is broken up under stirring to form a viscous, homogenous solution. After stirring for another 4 hours at room temperature, the resulting copolymer solution can be directly cast into film.

### Example 5

This Example illustrates the general procedure for the preparation of a copolymer from TPC, IPC, DAB, and PFMB (25%/25%/2.53%/47.7% mol) via solution condensation.

To a 250 ml three necked round bottom flask, equipped with a mechanical stirrer, a nitrogen inlet and outlet, are added PFMB (3.2024 g, 10.000 mmol), DAB (0.080 g 0.53 mmol) and dried DMAc (35 ml). After the PFMB and DAB dissolved completely, PrO (1.345 g, 23.159 mmol) was added to the solution. The solution is cooled to 0° C. Under stirring, IPC (1.058 g 5.211 mmol) was added to the solution, and the flask wall was washed with DMAc (1.0 ml). After 15 minutes, TPC (1.058 g, 5.211 mmol) was added to the solution and the flask wall was again washed with DMAc (1.0 ml). After two hours, benzoyl chloride (0.030 g, 0.216 mmol) was added to the solution and stirred for another two hours.

It is to be understood, although the temperature provided in the examples is room temperature, the temperature range can be between approximately −20° C. to approximately 50° C., and in some embodiments from approximately 0° C. to approximately 30° C.

### Preparation and Characterization of the Polymer Films

The polymer solution can be used directly for the film casting after polymerization. For the preparation of small films in a batch process, the solution is poured on a flat glass plate or other substrate, and the film thickness is adjusted by a doctor blade. After drying on the substrate, under reduced pressure, at 60° C. for several hours, the film is further dried at 200° C. under protection of dry nitrogen flow for 1 hour. The film is cured by heating at or near the polymer T_{g} under vacuum or in an inert atmosphere for several minutes. Mechanical removal from the substrate yields a free standing film greater than approximately 10 μm thick. The thickness of the free standing films can be adjusted by adjusting the solids content and viscosity of the polymer solution. It is to be understood that the film can be cured at least 280° C. or any temperature between approximately 90% and approximately 110% of the T_{g}. It is also understood that the batch process can be modified so that it can be carried out continuously by a roll-to-roll process by techniques known to those skilled in the art.

In one embodiment of this disclosure, the polymer solution may be solution cast onto a reinforcing substrate like thin glass, silica, or a microelectronic device. In this case, the process is adjusted so that the final polyamide film thickness is greater than approximately 5 μm.

The CTE and T_{g} are measured with a thermal mechanical analyzer (TA Q 400 TMA). The sample film has a thickness of approximately 20 μm, and the load strain is 0.05N. In one embodiment, the free standing film thickness is between approximately 20 μm and approximately 125 μm. In one embodiment, the film is adhered to a reinforcing substrate and the film thickness is <20 μm. In one embodiment, the CTE is less than approximately 20 ppm/° C., but it is understood that in other embodiments, the CTE is less than approximately 15 ppm/° C., less than approximately 10 ppm/° C., and less than approximately 5 ppm/° C. It is to be understood that within these embodiments the CTE can be less than approximately 19, 18, 17, 16, 15, 14, 13, 12, 11, 10, 9, 8, 7, 6, or 5 ppm/° C. The experimentally derived CTEs are the average of the CTE obtained from room temperature to about 250° C.

Film transparency is measured by determining the transmittance of a 10 μm thick film from 400 to 750 nm with a UV-Visible spectrometer (Shimadzu UV 2450).

The solvent resistance of the film is determined by immersing it in a selected solvent for 30 minutes at room temperature. The film is considered solvent resistant if it is substantially free of surface wrinkles, swelling, or any other visible damage after immersion. The films are useful as substrates for flexible electronic devices.

To determine the ratio of reactants necessary to obtain a soluble copolyamide that can be solution cast into a colorless film with a T_{g}>300 C, a CIE <20 ppm, and a transmittance >80% from 400 to 750 nm, a preliminary study can be conducted where the amount of reactants that do not contain free carboxyl groups are varied in a systematic manner. The properties of the films of the copolymers obtained are measured in order to determine suitable copolymer candidates (base polymers) for the incorporation of free carboxyl groups. Such studies are well understood by those skilled in the art. The following tables show experimental examples of the such studies used to determine some on the base polymers utilized in the present disclosure.

TABLE 1
Properties of films based on TPC/IPC/PFMB

| | CTE | | Film |
|---|---|---|---|
| TPC/IPC/PFMB | ppm/° C. | T_{g} ° C. | Transparency |
| 100/0/100 | — | — | Opaque |
| 90/10/100 | — | — | Opaque |
| 80/20/100 | — | — | Opaque |
| 75/25/100 | — | — | Opaque |
| 70/30/100 | 7.4 | 336 | Clear |
| (Example 1) | | | |
| 60/40/100 | 8.0 | 323 | Clear |
| 50/50/100 | 12.2 | 330 | Clear |
| 40/60/100 | 22.4 | 336 | Clear |
| 30/70/100 | 32.6 | 319 | Clear |
| 20/80/100 | 27.9 | 326 | Clear |
| 10/90/100 | 30.1 | 325 | Clear |
| 0/100/100 | 34.2 | 327 | Clear |

TABLE 2
Properties of films based on TPC/FDA/PFMB

| | CTE | | Film |
|---|---|---|---|
| TPC/FDA/PFMB | ppm/° C. | T_{g} ° C. | Transparency |
| 100/0/100 | — | — | Opaque |
| 100/10/90 | — | — | Opaque |
| 100/20/80 | 5.8 | 365 | Clear |
| (Example 2) | | | |
| 100/30/70 | 5.1 | 370 | Clear |
| 100/50/50 | 13.1 | 391 | Clear |
| 100/70/30 | 18.3 | 406 | Clear |
| 100/80/20 | 26.7 | 404 | Clear |
| 100/90/10 | 33.2 | 410 | Clear |
| 100/100/0 | >40 | >410 | Clear |

To determine the minimum amount of carboxyl groups necessary to thermally crosslink the copolymer without significantly changing the properties, a second preliminary study can be conducted where various amounts of a reactant containing free carboxyl groups are copolymerized with the mixture of reactants used to prepare the base polymer. Films of the copolymers obtained and their properties determined. For example, various amounts of DADP were copolymerized with the reactants used in the preparation of the base polymer made from a mixture of TPC, IPC and PFMB in a 70/30/100 ratio (Example 1). The films of the copolymers obtained containing DADP were thermally treated at 330° C. for 5 minutes. After curing, the film resistance to NMP was evaluated. The results are shown in Table 3.

TABLE 3
NMP resistance test for TPC/IPC/PFMB/DADP polymer films

| TPC/IPC/PFMB/DADP | NMP resistance |
|---|---|
| 70/30/99/1 | No |
| 70/30/97/3 (Example 3) | Yes |
| 70/30/95/5 | Yes |

The properties of polymer films based on Example 3 after curing are shown in Table 4. The composition of a copolymer containing DAB (Example 4), which was determined in an analogous manner, is also shown in Table 4 along with the properties of cured films of this polymer.

TABLE 4
Properties of films after curing

| | Example 3 | Example 4 |
|---|---|---|
| TPC | 70 | 75 |
| IPC | 30 | 25 |
| PFMB | 97 | 95 |
| DADP | 3 | 0 |
| DAB | 0 | 5 |
| Curing Conditions | 330° C. × 5 minutes | 330° C. × 10 minutes |
| T_{g} (° C.) | 334 | 350 |
| CTE (ppm/° C.) | 7 | 12 |
| T % at 400 nm | 80 | 81 |
| DMAc resistance | Yes | Yes |
| NMP resistance | Yes | Yes |
| DMSO resistance | Yes | Yes |

The cured films of this disclosure are resistant to both inorganic and organic solvents. The film solvent resistance can be evaluated quickly by analyzing the resistance to NMP, a commonly used strong solvent. It has been found that films resistant to this solvent are also resistant to other polar solvents.

The following are exemplary polymers that can be used in this disclosure −1) about 50 to about 70 mol % TPC, about 30 to about 50 mol % IPC, about 90 to about 99 mol % PFMB, and about 1 to about 10 mol % 4,4′-Diaminodiphenic acid (DADP); 2) about 50 to about 70 mol % TPC, about 25 to about 50 mol % IPC, about 90 to about 96 mol % PFMB, and about 4 to about 10 mol % 3,5-diaminobenzoic acid (DAB); 3) about 100 mol % TPC, about 25 to about 85 mol % PFMB, about 15 to about 50 mol % 9,9-Bis(4-aminophenyl)fluorine (FDA), and about 1 to about 10 mol % DADP; and 4) about 100 mol % TPC, about 50 to about 85 mol % PFMB, about 15 to about 50 mol % FDA, and about 4 to about 10 mol % DAB.

The embodiments have been described, hereinabove. It will be apparent to those skilled in the art that the above methods and apparatuses may incorporate changes and modifications without departing from the general scope of this disclosure. It is intended to include all such modifications and alterations insofar as they come within the scope of the appended claims or the equivalents thereof. Although the description above contains much specificity, this should not be construed as limiting the scope of the disclosure, but as merely providing illustrations of some of the embodiments of this disclosure. Various other embodiments and ramifications are possible within its scope.

Furthermore, notwithstanding that the numerical ranges and parameters setting forth the broad scope of the disclosure are approximations, the numerical values set forth in the specific examples are reported as precisely as possible. Any numerical value, however, inherently contain certain errors necessarily resulting from the standard deviation found in their respective testing measurements.

The present disclosure, in one aspect, is directed toward a solution of polyamide that can be used to prepare transparent films prepared from aromatic copolyamides with T_{g}s greater than 300° C. that have CTEs less than 20 ppm/° C. Examples of the solution of polyamide include solutions of the polyamides in N,N-dimethylacetamide (DMAc), N-methyl-2-pyrrolidinone (NMP), or other solvents. Further, the films are cast using the solution of polyamide. The present disclosure can be produced in the absence of an inorganic salt. Surprisingly, it was discovered that the incorporation of a few free, pendant carboxyl groups along the polyamide backbones allowed the films to be thermally cured at elevated temperatures, which greatly increased their solvent resistance.

According to one embodiment of this disclosure, a process is provided for manufacturing a aromatic copolyamide film comprising the steps of (A) forming a mixture of two or more aromatic diamines wherein at least one of the diamines contains one or more free carboxylic acid groups, such that the amount of the carboxylic acid containing diamine is greater than approximately 1 mole percent and less than approximately 30 mole percent of the total diamine mixture; (B) dissolving the aromatic diamine mixture in a solvent; (C) reacting the diamine mixture with at least one aromatic diacid dichloride, wherein hydrochloric acid and a polyamide solution is generated; (D) eliminating the hydrochloric acid with a reagent; (E) casting the polyamide solution into a film; and as necessary, (F) curing the film at a temperature, wherein the temperature is at least 90% of the glass transition temperature of the film. The curing process involves heating the polymer films containing a free acid group near the T_{g} for several minutes under an inert atmosphere or under reduced pressure. After the curing process, the film resists dissolution and/or swelling in commonly used organic solvents, including NMP, DMAc, dimethylsulfoxide (DMSO), etc. The word “eliminating” is defined to mean physically trapping, neutralizing, and/or chemically reacting the hydrochloric acid.

According to another embodiment of this disclosure, a transparent aromatic copolyamide film is produced having at least two repeat units of a general formula (I) and (II):

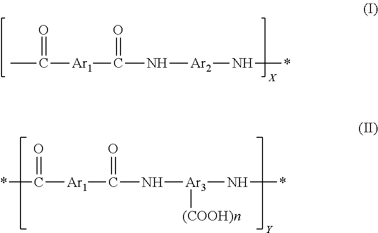

wherein n=1 to 4 (including, without limitation, 1, 2, 3, and 4), wherein Ar₁ is selected from the group of aromatic units which form aromatic diacid chlorides:

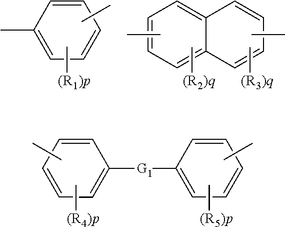

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. Ar₂ is selected from the group of aromatic units which form diamines:

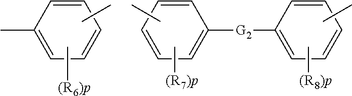

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. Ar₃ is selected from the group of aromatic units which form diamines containing free carboxylic acid group:

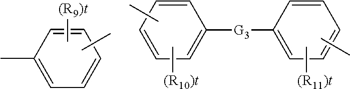

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls like trifluoromethyl, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. It should be understood that the copolymer may contain multiple repeat units with structures (I) and (II) where Ar₁, Ar₂, and Ar₃ may be the same or different.

According to yet another embodiment of this disclosure, a method of preparing a transparent film having a CTE less than 20 ppm/° C. that is stable for at least one hour at 300° C. comprising the steps of:

(A) reacting a mixture of aromatic diamines, in a solvent, wherein at least one of the diamines includes a pendant carboxylic acid group of the general formula (III):

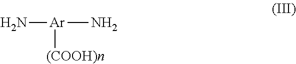

wherein n=1 to 4 (including, without limitation, 1, 2, 3, and 4), wherein Ar is selected from the group of aromatic units which form diamines containing free carboxylic acid group:

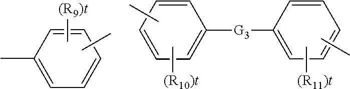

wherein m=1 or 2, wherein t=1 to 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene; with aromatic diacid chlorides to afford a copolyamide containing pendant carboxyl groups;

(B) solution casting the resulting copolyamide into a film; and,

(C) curing the film to induce solvent resistance.

According to one embodiment of this disclosure, the temperature of the curing is at least approximately 90% of the glass transition temperature of the film and/or approximately 280° C.

According to one embodiment of this disclosure, the temperature of the curing is between approximately 90% and approximately 110% of the glass transition temperature of the film and/or approximately 280° C.

According to one embodiment of this disclosure, the film is produced in the absence of inorganic salt.

According to one embodiment of this disclosure, the process further comprises a step of curing the film during and/or after the step (f).

According to one embodiment of this disclosure, the film transparency is >80% at 400 and 750 nm before a resulting film is cured.

According to one embodiment of this disclosure, the film curing temperature is held at least approximately 280° C. and/or between approximately 90% and approximately 110% of the glass transition temperature of the film for at least approximately 3 minutes.

According to one embodiment of this disclosure, the film transparency is ˜88% at 550 nm after the film is cured.

According to one embodiment of this disclosure, a resulting film is cured at a temperature which allows the film to be chemically resistant to polar solvents.

According to one embodiment of this disclosure, a resulting film coefficient of thermal expansion is less than approximately 10 ppm/° C.

According to one embodiment of this disclosure, a resulting film undergoes no significant loss in transparency when heated for at least one hour at 300° C.

According to one embodiment of this disclosure, the film is cured for at least 5 minutes.

According to one embodiment of this disclosure, the film displays resistance to swelling and dissolving in an inorganic solvent after being cured for about 5 minutes.

According to one embodiment of this disclosure, the resulting film has a thickness of greater than approximately 10 μm.

According to one embodiment of this disclosure, the resulting film on the reinforcing base has a thickness of greater than approximately 5 μm.

According to one embodiment of this disclosure, the coefficient of thermal expansion of the resulting copolyamide film is less than approximately 10 ppm/° C.

According to one embodiment of this disclosure, the resulting film is insoluble to organic solvents, wherein the film is produced in the absence of inorganic salt.

According to one embodiment of this disclosure, the resulting film resists dissolution and swelling when exposed to an organic solvent.

According to one embodiment of this disclosure, the base is a glass film with a thickness greater than approximately 50 μm.

Polyamides containing free pendant carboxylic groups have been prepared using 3,5-diaminobenzoic acid (DAB) or 4,4′-diaminodiphenic acid (DADP). In U.S. Pat. No. 5,160,619, polyamides containing small amounts of DAB (less than 1 mol %) useful for reverse osmosis membranes are described. In U.S. Pat. No. 5,039,785, polyamides containing more than 10 mol % DADP useful for high performance fibers are described. However, there has been no attempt to crosslink films of these polymers by heating them to temperatures near their T_{g}s. Even if the inventors had attempted to crosslink them in this unexpected manner, in the case of the polymers containing DAB, the carboxylic acid content would have been too low to affect cross linking, and in the case of the DADP polymers, the degree of cross linking would have been so high that the films would have been extremely brittle and unsuitable for flexible substrates.

Thus, it was surprising to find that the incorporation of about 1 mole % to about 30 mole % of a diamine, containing free carboxyl groups, in the copolyamides in this disclosure could allow the polymers to be crosslinked within a short period of time (minutes) when their films were heated at temperatures close to their T_{g}s. For example, the incorporation of these amounts of DADP or DAB resulted in films resistant to solvents commonly used in the microelectronic industry that had retained their transparency through the crosslinking process. The crosslinked films displayed high glass transition temperatures (T_{g}>300° C.), and low coefficients of thermal expansion (<20 ppm/° C.). Thus, the crosslinked films can be used as flexible substrates that will enable the high temperature fabrication of thin film transistors needed for a wide range of microelectronic applications, particularly for ruggedized or flexible organic light emitting diode (OLED) displays. No available material exhibits all of these properties.

The polymer substrate films in the present disclosure expand the utilization of AMOLEDs in portable devices by improving device electrical efficiency and the consumer experienced robustness of the display. In addition to the standard OLED display market, the substrate of the present disclosure will enable the development of the flexible display market. These displays can be used for conformable displays that can be integrated onto clothing, flexible e-paper and e-book displays, displays for smartcards, and a host of other new applications. For example, the polymer substrate films in the present disclosure can be used for flexible sensors. The new devices produced from the polymer substrate films in the present disclosure can dramatically impact daily life, by decreasing the cost and increasing accessibility and portability of information.

Additionally, the polymers in the present disclosure can be prepared in a common organic solvent at room temperature (approximately 15° C. to approximately 25° C.). These polymers can be produced in the absence of an inorganic salt. The resulting colorless and homogenous polymer solution can be used directly for subsequent film casting. No special polymerization reactor and no polymer isolation procedure is required. However, after the polymers are heated at temperatures near their T_{g}s for several minutes, the polymer films are inherently insoluble and chemically resistant to swelling when exposed to inorganic or organic solvents. Thus, the process is amenable to scale-up to metric ton quantities.

The polymers of the present disclosure are soluble in polar aprotic solvents without the need for the presence of inorganic salts. They can be solution cast in a batch process, or continuously cast directly from their polymerization mixtures and cured using a roll-to-roll process to yield free standing transparent films with thickness greater than 20 μm. Alternatively, the polymer solutions may be solution cast onto a reinforcing substrate (base) like thin glass or a microelectronic device and cured to form films less than 20 μM. The films display high T_{g}s (>300° C.), low CTEs (<20 ppm/° C.), high transparencies (T>180% between 400 to 750 nm), excellent mechanical properties (tensile strengths >200 MPa), and low moisture absorptions (<2% @ 100% humidity at room temperature). Furthermore, the films show excellent chemical resistance after they are heated to temperatures of at least 90% that of their T_{g}s for short periods of time.

The copolyamides were prepared by polymerizing one or more aromatic diacid dichlorides as shown in the following general structures:

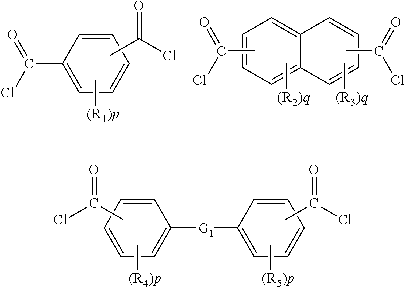

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

And two or more aromatic diamines as shown in the following general structures:

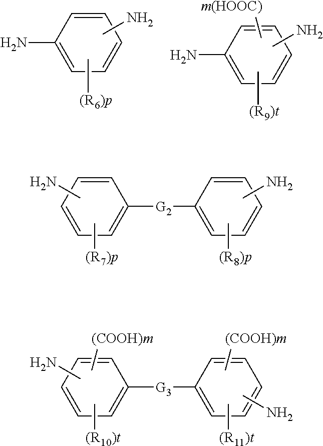

wherein p=4, m=1 or 2, and t=1 to 3, wherein R₆, R₇, R₈, R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₆ can be different, each R₇ can be different, each R₈ can be different, each R₉ can be different, each R₁₀ can be different, and each R₁₁ can be different. G₂ and G₃ are selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

This disclosure, in one aspect, relates to a solution of polyamide comprising an aromatic copolyamide and a solvent.

According to one of embodiments of this disclosure, the aromatic copolyamide comprises at least two repeat units, and at least one of the repeat units has one or more free carboxylic acid group.

According to one of embodiments of this disclosure, the amount of the carboxylic acid containing repeat unit(s) are greater than approximately 1 mole percent and less than approximately 30 mole percent, preferably greater than approximately 2 mole percent and less than approximately 20 mole percent, and more preferably approximately 2 mole percent and less than approximately 10 mole percent of the total repeat units.

According to one of embodiments of this disclosure, the carboxylic acid containing repeat unit is formed by reacting 4,4′-diaminodiphenic acid or 3,5-diaminobenzoic acid with at least one aromatic diacid dichloride.

According to one of embodiments of this disclosure, at least one repeat unit(s) is formed by reacting an aromatic diamine selected from the group consisting of 2,2′-bistrifluoromethylbenzidine 9,9-bis(4-aminophenyl) fluorene, 9,9-bis(3-fluoro-4-aminophenyl) fluorene, 2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl with at least one aromatic diacid dichloride.

According to one of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride. According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol(IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone(NMP), dimethylsulfoxide (DMSO), butyl cellosolve, methyl cellosolve, ethyl cellosolve, ethyleneglycol monobutylether, propyleneglycol monobutylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one of embodiments of this disclosure, the solution of polyamide is for use in the process for manufacturing a display element, an optical element or an illumination element, comprising the steps of:

a) applying a solution of an aromatic copolyamide onto a base;

b) forming a polyamide film on the base after the applying step (a); and

c) forming the display element, the optical element or the illumination element on the surface of polyamide film.

Furthermore, this disclosure, in one aspect, relates to a solution of polyamide comprising an aromatic copolyamide and a polar solvent.

According to one of embodiments of this disclosure, the aromatic copolyamide has at least two repeat units of a general formula (I) and (II):

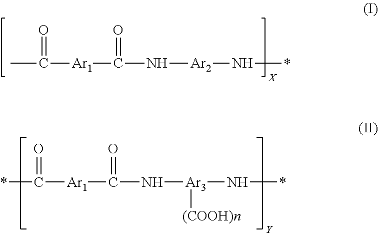

wherein n=1 to 4 (including, without limitation, 1, 2, 3, and 4), wherein Ar₁ is selected from the group of aromatic units which form aromatic diacid chlorides:

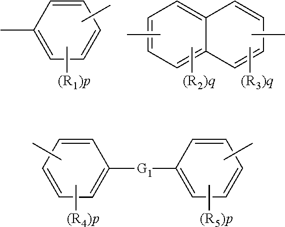

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. Ar₂ is selected from the group of aromatic units which form diamines:

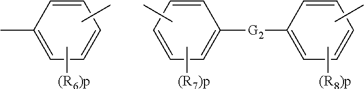

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. Ar₃ is selected from the group of aromatic units which form diamines containing free carboxylic acid group:

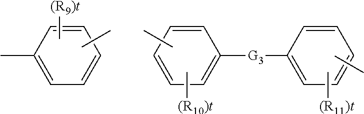

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls like trifluoromethyl, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. It should be understood that the copolymer may contain multiple repeat units with structures (I) and (II) where Ar₁, Ar₂ and Ar₃ may be the same or different.

According to one of embodiments of this disclosure, X is the molar ratio of the repeat structure (I), wherein X is from 0.70 to 0.99, and Y is the molar ratio of the repeat structure (II), wherein Y is from 0.01 to 0.30.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobutylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one of embodiments of this disclosure, the solution of polyamide is for use in the process for manufacturing a display element, an optical element or an illumination element, comprising the steps of:

a) applying a solution of an aromatic copolyamide onto a base;

b) forming a polyamide film on the base after the applying step (a); and

c) forming the display element, the optical element or the illumination element on the surface of polyamide film.

Furthermore, this disclosure, in one aspect, relates to a solution of polyamide comprising an aromatic copolyamide and a solvent.

According to one of embodiments of this disclosure, the aromatic copolyamide has at least two repeat structures, and one of the repeat structures is repeat structure (V):

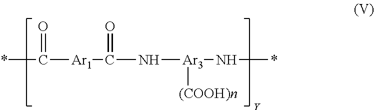

wherein n=1 to 4 (including, without limitation, 1, 2, 3, and 4), wherein Y is the molar ratio of the repeat structure (V) with respect to all other repeat structures, and Y is from 0.01 to 0.30, wherein Ar₁ is selected from the group of aromatic units which form aromatic diacid chlorides:

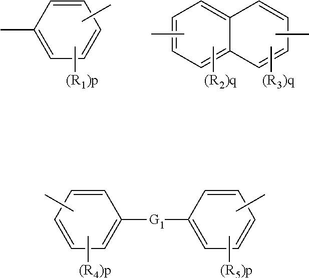

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

Ar₃ is selected from the group of aromatic units which form diamines containing free carboxylic acid group:

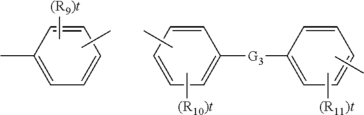

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls like trifluoromethyl, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. It should be understood that the copolymer may contain multiple repeat units with structures (V) where Ar₁, and Ar₃ may be the same or different.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobutylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one of embodiments of this disclosure, the solution of polyamide is for use in the process for manufacturing a display element, an optical element or an illumination element, comprising the steps of:

a) applying a solution of an aromatic copolyamide onto a base;

b) forming a polyamide film on the base after the applying step (a); and

c) forming the display element, the optical element or the illumination element on the surface of polyamide film.

Furthermore, this disclosure, in another aspect, relates to a process of manufacturing the polyamide solution according to this disclosure.

According to one embodiment of this disclosure, a process is provided for manufacturing a solution of an aromatic copolyamide comprising the steps of:

a) forming a mixture of two or more aromatic diamines where at least one of the diamines contains one or more free carboxylic acid groups, such that the amount of carboxylic acid containing diamine is greater than approximately 1 mole percent and less than approximately 30 mole percent of the total diamine mixture;

b) dissolving the aromatic diamine mixture in a solvent;

c) reacting the diamine mixture with at least one aromatic diacid dichloride, wherein hydrochloric acid and a polyamide solution is generated; and,

d) eliminating the hydrochloric acid with a reagent.

The word “eliminating” is defined to mean physically trapping, neutralizing, and/or chemically reacting the hydrochloric acid.

According to one of embodiments of this disclosure, the diamine containing a carboxylic acid group is 4,4′-diaminodiphenic acid or 3,5-diaminobenzoic acid.

According to one of embodiments of this disclosure, the aromatic diamine is selected from the group comprising 4,4′-diamino-2,2′-bistrifluoromethylbenzidine, 9,9-bis(4-aminophenyl) fluorine, and 9,9-bis(3-fluoro-4-aminophenyl)fluorine, 4,4′-diamino-2,2′bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl.

According to one of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobutylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof; or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one of embodiments of this disclosure, the reagent is added to the mixture before or during the reacting step (c). Adding the reagent before or during the reaction step (c) can reduce degree of viscosity and generation of lumps in the mixture after the reaction step (c), and therefore, can improve productivity of the solution of the polyamide. These effects are significant specifically when the reagent is organic reagent, such as propylene oxide.

According to one of embodiments of this disclosure, the reaction of the reagent with the hydrochloric acid forms a volatile product.

According to one of embodiments of this disclosure, the reagent is organic neutralizing reagent.

According to one of embodiments of this disclosure, the reagent is propylene oxide.

According to one of embodiments of this disclosure, the solution of an aromatic copolyamide is produced in the absence of inorganic salt.

According to one of embodiments of this disclosure, the solution of an aromatic copolyamide is for use in the process for manufacturing a display element, an optical element or an illumination element, comprising the steps of:

a) applying a solution of an aromatic copolyamide onto a base;

b) forming a polyamide film on the base after the applying step (a); and

c) forming the display element, the optical element or the illumination element on the surface of polyamide film.

Furthermore, this disclosure, in another aspect, relates to a process of manufacturing the polyamide solution according to this disclosure.

According to one embodiment of this disclosure, a process is provided for manufacturing a solution of an aromatic copolyamide comprising the steps of:

reacting a mixture of aromatic diamines with at least one aromatic diacid chloride in a solvent to form a polyamide wherein a carboxyl group is incorporated along the polyamide backbone, wherein at least one of the diamines includes a pendant carboxylic acid group of the general formula (III):

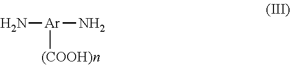

wherein n=1 to 4 (including, without limitation, 1, 2, 3, and 4), wherein Ar is selected from the group of aromatic units which form diamines containing free carboxylic acid group:

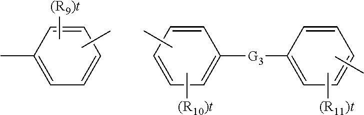

wherein m=1 or 2, wherein t=1 to 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene; with aromatic diacid chlorides to afford a copolyamide containing pendant carboxyl groups.

According to one embodiment of this disclosure, the molar percent of the carboxylic acid is greater than approximately 1 and less than approximately 30.

According to one of embodiments of this disclosure, the diamine containing a carboxylic acid group is 4,4′-diaminodiphenic acid or 3,5-diaminobenzoic acid.

According to one of embodiments of this disclosure, the aromatic diamine is selected from the group comprising 4,4′-diamino-2,2′-bistrifluoromethylbenzidine, 9,9-bis(4-aminophenyl) fluorine, and 9,9-bis(3-fluoro-4-aminophenyl)fluorine, 4,4′-diamino-2,2′bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl.

According to one of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one embodiment of this disclosure, the solution of an aromatic copolyamide is for use in the process for manufacturing a display element, an optical element or an illumination element, comprising the steps of:

a) applying a solution of an aromatic copolyamide onto a base;

b) forming a polyamide film on the base after the applying step (a); and

c) forming the display element, the optical element or the illumination element on the surface of polyamide film.

The solution of the aromatic copolyamide according to this disclosure can improve productivity of manufacturing of a display element, an optical element or an illumination element, including OLED by adopting the process according to this disclosure.

Furthermore, this disclosure, in another aspect, relates to a process of manufacturing a display element, an optical element or an illumination element.

According to one embodiment of this disclosure, a process is provided for manufacturing a display element, an optical element or an illumination element comprising the steps of:

a) forming a mixture of two or more aromatic diamines where at least one of the diamines contains one or more free carboxylic acid groups, such that the amount of carboxylic acid containing diamine is greater than approximately 1 mole percent and less than approximately 30 mole percent of the total diamine mixture;

b) dissolving the aromatic diamine mixture in a solvent;

c) reacting the diamine mixture with at least one aromatic diacid dichloride, wherein hydrochloric acid and a polyamide solution is generated;

d) eliminating the hydrochloric acid with a reagent to obtain a polyamide solution;

e) applying a solution of an aromatic copolyamide onto a base;

f) forming a polyamide film on the base after the applying step (e); and

g) forming the display element, the optical element or the illumination element on the surface of the polyamide film.

The word “eliminating” is defined to mean physically trapping, neutralizing, and/or chemically reacting the hydrochloric acid.

According to one of embodiments of this disclosure, the diamine containing a carboxylic acid group is 4,4′-diaminodiphenic acid or 3,5-diaminobenzoic acid.

According to one of embodiments of this disclosure, the aromatic diamine is selected from the group comprising 4,4′-diamino-2,2′-bistrifluoromethylbenzidine, 9,9-bis(4-aminophenyl) fluorine, and 9,9-bis(3-fluoro-4-aminophenyl)fluorine, 4,4′-diamino-2,2′bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl.

According to one of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one of embodiments of this disclosure, the reagent is added to the mixture before or during the reacting step (c). Adding the reagent before or during the reaction step (c) can reduce degree of viscosity and generation of lumps in the mixture after the reaction step (c), and therefore, can improve productivity of the solution of the polyamide. These effects are significant specifically when the reagent is organic reagent, such as propylene oxide.

According to one of embodiments of this disclosure, the reaction of the reagent with the hydrochloric acid forms a volatile product.

According to one of embodiments of this disclosure, the reagent is organic neutralizing reagent.

According to one of embodiments of this disclosure, the process further comprises a step of curing the film during and/or after the step (f). Although curing at an elevated temperature can render resistance to swelling and dissolving in an inorganic solvent to the polyamide film, this step of curing is optional. In case the barrier is on the polyamide film, a barrier layer that can render resistance to swelling and dissolving in an inorganic solvent

According to one of embodiments of this disclosure, the temperature of the curing is at least approximately 90% of the glass transition temperature of the film and/or approximately 280° C.

According to one of embodiments of this disclosure, the temperature is between approximately 90% and approximately 110% of the glass transition temperature of the film and/or approximately 280° C.

According to one of embodiments of this disclosure, the film is produced in the absence of inorganic salt.

According to one of embodiments of this disclosure, the process further comprises the step of:

h) de-bonding, from the base, the display element, the optical element or the illumination element formed on the base.

Furthermore, this disclosure, in another aspect, relates to a process of manufacturing a display element, an optical element or an illumination element.

According to one embodiment of this disclosure, a process is provided for manufacturing a display element, an optical element or an illumination element comprising the steps of:

a) applying a solution of an aromatic copolyamide onto a base;

b) forming a polyamide film on the base after the applying step (a); and

c) forming the display element, the optical element or the illumination element on the surface of polyamide film;

wherein the solution of an aromatic copolyamide comprising an aromatic copolyamide and a solvent,

wherein the aromatic copolyamide comprises at least two repeat units of general formulas (I) and (II):

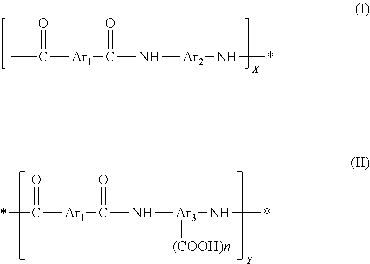

wherein n=1 to 4 (including, without limitation, 1, 2, 3, and 4), wherein Ar₁ is selected from the group of aromatic units which form aromatic diacid chlorides:

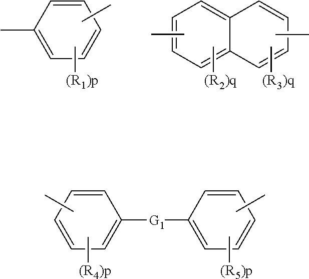

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. Ar₂ is selected from the group of aromatic units which form diamines:

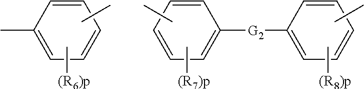

wherein p=4, wherein R₆, R₇, R₈ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, substituted aryl such as halogenated aryls, alkyl ester, and substituted alkyl esters, and combinations thereof. It is to be understood that each R₆ can be different, each R₇ can be different, and each R₈ can be different. G₂ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

Ar₃ is selected from the group of aromatic units which form diamines containing free carboxylic acid group:

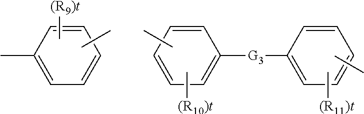

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls like trifluoromethyl, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. It should be understood that the copolymer may contain multiple repeat units with structures (I) and (II) where Ar₁, Ar₂, and Ar₃ may be the same or different.

According to one embodiment of this disclosure, the ratio of X and Y is selected so that the copolyamide is soluble in solvents described below, and can be solution cast into a clear film that has a CTE <20 ppm/° C.;

According to one embodiment of this disclosure, X is the molar fraction of the repeat structure (I), wherein X is from 70 to 99%, and Y is the molar fraction of the repeat structure (II), wherein Y is from 1 to 30%.

According to one embodiment of this disclosure, the copolymer contains multiple repeat units with structures (I) and (II) where Ar₁, Ar₂, and Ar₃ are the same or different.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one embodiment of this disclosure, the process further comprises a step of curing the film during and/or after the step (b). Although curing at an elevated temperature can render resistance to swelling and dissolving in an inorganic solvent to the polyamide film, this step of curing is optional. In case the barrier is on the polyamide film, a barrier layer that can render resistance to swelling and dissolving in an inorganic solvent

According to one embodiment of this disclosure, the film transparency is >80% at 400 and 750 nm before a resulting film is cured.

According to one embodiment of this disclosure, a resulting film transparency is >80% at 400 and 750 nm after a film is cured.

According to one embodiment of this disclosure, the film curing temperature is held at least approximately 280° C. and/or approximately 90% to approximately 110% of the glass transition temperature of the film for at least approximately 3 minutes.

According to one embodiment of this disclosure, the film transparency is ˜88% at 550 nm after the film is cured.

According to one embodiment of this disclosure, a resulting film is cured at a temperature of approximately 280° C. and/or between approximately 90% and approximately 110% of the glass transition temperature of the film.

According to one embodiment of this disclosure, a resulting film is cured at a temperature which allows the film to be chemically resistant to polar solvents.

According to one embodiment of this disclosure, a resulting film coefficient of thermal expansion is less than approximately 10 ppm/° C.

According to one embodiment of this disclosure, a resulting film undergoes no significant loss in transparency when heated for at least one hour at 300° C.

According to one embodiment of this disclosure, the process further comprises the step of:

d) de-bonding, from the base, the display element, the optical element or the illumination element formed on the base.

Furthermore, this disclosure, in another aspect, relates to a process of manufacturing a display element, an optical element or an illumination element.

According to one embodiment of this disclosure, a process is provided for manufacturing a display element, an optical element or an illumination element comprising the steps of:

a) reacting a mixture of aromatic diamines with at least one aromatic diacid chloride in a solvent to form a polyamide wherein a carboxyl group is incorporated along the polyamide backbone, wherein at least one of the diamines includes a pendant carboxylic acid group of the general formula (III):

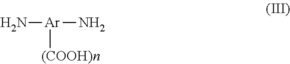

wherein n=1 to 4 (including, without limitation, 1, 2, 3, and 4), wherein Ar is selected from the group of aromatic units which form diamines containing free carboxylic acid group:

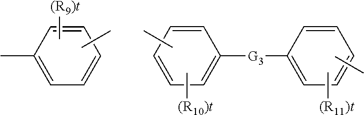

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene; with aromatic diacid chlorides to afford a copolyamide containing pendant carboxyl groups;

b) directly applying the resulting copolyamide solution onto a base;

c) forming a polyamide film on the base after the applying step (b); and

d) forming the display element, the optical element or the illumination element on the surface of the polyamide film.

According to one embodiment of this disclosure, the molar percent of the carboxylic acid is greater than approximately 1 and less than approximately 30.

According to one of embodiments of this disclosure, the diamine containing a carboxylic acid group is 4,4′-diaminodiphenic acid or 3,5-diaminobenzoic acid.

According to one of embodiments of this disclosure, the aromatic diamine is selected from the group comprising 4,4′-diamino-2,2′-bistrifluoromethylbenzidine, 9,9-bis(4-aminophenyl) fluorine, and 9,9-bis(3-fluoro-4-aminophenyl)fluorine, 4,4′-diamino-2,2′bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl.

According to one of embodiments of this disclosure, the at least one aromatic diacid dichloride is selected from the group comprising terephthaloyl dichloride, isophthaloyl dichloride, 2,6-naphthaloyl dichloride, and 4,4,-biphenyldicarbonyl dichloride.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one embodiment of this disclosure, the process further comprises a step of curing the film during and for after the step (c). Although curing at an elevated temperature can render resistance to swelling and dissolving in an inorganic solvent to the polyamide film, this step of curing is optional. In case the barrier is on the polyamide film, a barrier layer that can render resistance to swelling and dissolving in an inorganic solvent

According to one embodiment of this disclosure, the curing temperature is at least about 280° C. and/or between approximately 90% and approximately 110% of the glass transition temperature of the film.

According to one embodiment of this disclosure, the film is cured for at least 5 minutes.

According to one embodiment of this disclosure, the film displays resistance to swelling and dissolving in an inorganic solvent after being cured for about 5 minutes.

According to one embodiment of this disclosure, the resulting film has a thickness of greater than approximately 10 μm.

According to one embodiment of this disclosure, the resulting film on the reinforcing base has a thickness of greater than approximately 5 μm.

According to one embodiment of this disclosure, the coefficient of thermal expansion of the resulting copolyamide film is less than approximately 10 ppm/° C.

According to one embodiment of this disclosure, the resulting film resists dissolution and swelling when exposed to an organic solvent.

According to one embodiment of this disclosure, the process further comprises the step of:

e) de-bonding, from the base, the display element, the optical element or the illumination element formed on the base.

Furthermore, this disclosure, in another aspect, relates to a process of manufacturing a display element, an optical element or an illumination element.

According to one embodiment of this disclosure, a process is provided for manufacturing a display element, an optical element or an illumination element comprising the steps of:

a) applying a solution of an aromatic copolyamide onto a base;

b) forming a polyamide film on the base after the applying step (a); and

c) forming the display element, the optical element or the illumination element on the surface of polyamide film;

wherein the solution of an aromatic copolyamide comprising an aromatic copolyamide and a solvent, wherein the aromatic copolyamide comprises at least two repeat structures, wherein one of the repeat structures is repeat structure (V)

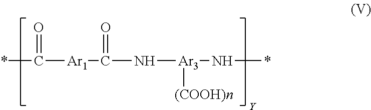

wherein n=1 to 4 (including, without limitation, 1, 2, 3, and 4), wherein Y is the molar ratio of the repeat structure (V) with respect to all other repeat structures, and Y is from 0.01 to 0.10, wherein Ar₁ is selected from the group of aromatic units which form aromatic diacid chlorides:

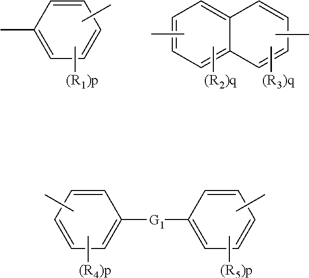

wherein p=4, q=3, and wherein R₁, R₂, R₃, R₄, R₅ are selected from the group comprising hydrogen, halogen (fluoride, chloride, bromide, and iodide), alkyl, substituted alkyl such as halogenated alkyls, nitro, cyano, thioalkyl, alkoxy, substituted alkoxy such as halogenated alkoxy, aryl, or substituted aryl such as halogenated aryls, alkyl ester and substituted alkyl esters, and combinations thereof. It is to be understood that each R₁ can be different, each R₂ can be different, each R₃ can be different, each R₄ can be different, and each R₅ can be different. G₁ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene.

Ar₃ is selected from the group of aromatic units which form diamines containing free carboxylic acid group:

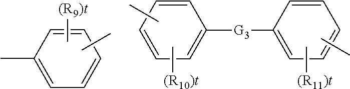

wherein t=1 to 3, wherein R₉, R₁₀, R₁₁ are selected from the group comprising hydrogen, halogen (fluoride, chloride, bromide, and iodide), alkyl, substituted alkyl such as halogenated alkyls like trifluoromethyl, nitro, cyano, thioalkyl, alkoxy, substituted alkoxy such as a halogenated alkoxy, aryl, substituted aryl such as halogenated aryls, alkyl ester, and substituted alkyl esters, and combinations thereof. It is to be understood that each R₉ can be different, each R₁₀ can be different, and each R₁₁ can be different. G₃ is selected from a group comprising a covalent bond; a CH₂ group; a C(CH₃)₂ group; a C(CF₃)₂ group; a C(CX₃)₂ group, wherein X is a halogen; a CO group; an O atom; a S atom; a SO₂ group; a Si (CH₃)₂ group; 9,9-fluorene group; substituted 9,9-fluorene; and an OZO group, wherein Z is a aryl group or substituted aryl group, such as phenyl group, biphenyl group, perfluorobiphenyl group, 9,9-bisphenylfluorene group, and substituted 9,9-bisphenylfluorene. It should be understood that the copolymer may contain multiple repeat units with structures (V) where Ar₁, and Ar₃ may be the same or different.

According to one embodiment of this disclosure, the film thickness is greater than approximately 10 μm.

According to one embodiment of this disclosure, the film thickness is between approximately 10 μm and approximately 100 μm.

According to one embodiment of this disclosure, the film is adhered to a base and wherein the film thickness is greater than approximately 5 μm.

According to one embodiment of this disclosure, the base is a glass film with a thickness greater than approximately 50 μM.

According to one of embodiments of this disclosure, from the point of enhancement of solubility of the polyamide to the solvent, the solvent is a polar solvent or a mixed solvent comprising one or more polar solvents. In one of embodiments, from the point of enhanced solubility of the polyamide to the solvent, the polar solvent is methanol, ethanol, propanol, isopropanol (IPA), buthanol, acetone, methyl ethyl ketone (MEK), methyl isobuthyl ketone (MIBK), toluene, cresol, xylene, propyleneglycol monomethylether acetate (PGMEA), N,N-dimethylacetamide (DMAc) or N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), N,N-dimethylformamide (DMF), a combination thereof, or a mixed solvent comprising at least one of polar solvent thereof.

According to one of embodiments of this disclosure, the polar solvent is an organic and/or an inorganic solvent.

According to one of embodiments of this disclosure, one or both of the terminal —COOH group and terminal —NH₂ group of the aromatic polyamide are end-capped. The end-capping of the terminal is preferable from the point of enhancement of heat resistance property of the polyamide film. The terminal of the polyamide can be end-capped by the reaction of polymerized polyamide with benzoyl chloride when the terminal of Polyamide is —NH₂, or reaction of polymerized PA with aniline when the terminal of Polyamide is —COOH. However, the method of end-capping is not limited to this method.

According to one embodiment of this disclosure, the process further comprises a step of curing the film during and/or after the step (b). Although curing at an elevated temperature can render resistance to swelling and dissolving in an inorganic solvent to the polyamide film, this step of curing is optional. In case the barrier is on the polyamide film, a barrier layer that can render resistance to swelling and dissolving in an inorganic solvent

According to one embodiment of this disclosure, the film is cured between approximately 90% and approximately 110% of the glass transition temperature of the film and/or approximately 280° C.

According to one embodiment of this disclosure, the film has a glass transition temperature greater than approximately 280° C. and a coefficient of thermal expansion of less than approximately 20 ppm/° C.

According to one embodiment of this disclosure, the optical transmittance of the film is greater than approximately 80% between 400 nm and 750 nm.

According to one embodiment of this disclosure, the coefficient of thermal expansion is less than approximately 10 ppm/° C.

According to one embodiment of this disclosure, the process further comprises the step of:

d) de-bonding, from the base, the display element, the optical element or the illumination element formed on the base.

Obviously, numerous modifications and variations of the present invention are possible in light of the above teachings. It is therefore to be understood that within the scope of the appended claims, the invention may be practiced otherwise than as specifically described herein.

What is claimed is:

1. A solution of polyamide, comprising;
an aromatic copolyamide; and
a solvent,
wherein the aromatic copolyamide comprises at least two repeat units, and at least one of the repeat units has at least one free carboxylic acid group, and
wherein the amount of repeat unit containing the free carboxylic acid group is greater than approximately 1 mole percent and less than approximately 30 mole percent of the total repeat units.

2. The solution according to claim 1, wherein the solvent is a polar solvent or a mixed solvent comprising one or more polar solvents.

3. A solution of polyamide, comprising;
an aromatic copolyamide; and
a solvent,
wherein the aromatic copolyamide comprises at least two repeat units of general formulas (I) and (II): 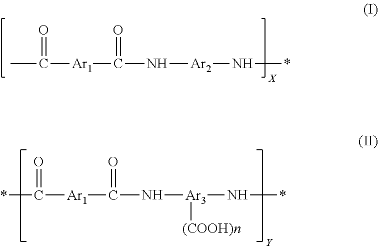
where n=1 to 4, the ratio of X and Y is selected such that the copolyamide is soluble in polar aprotic solvents, Ar₁ is selected from the group consisting of: 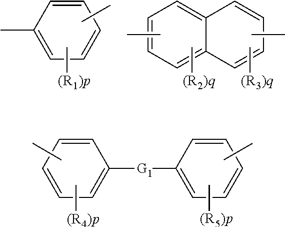
where p=4, q=3, and R₁, R₂, R₃, R₄, R₅ are selected from the group consisting of hydrogen, halogen, alkyl, substituted alkyl, alkoxy, substituted alkoxy, aryl, or substituted aryl, alkyl ester and substituted alkyl esters, and combinations thereof, G₁ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, Z is a aryl group or substituted aryl group, Ar₂ is selected from the group consisting of: 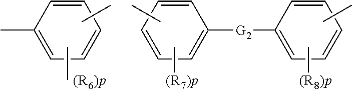
where p=4, R₆, R₇, R₈ are selected from the group consisting of hydrogen, halogen, alkyl, substituted alkyl, alkoxy, substituted alkoxy, aryl, substituted aryl, alkyl ester, and substituted alkyl esters, and combinations thereof, G₂ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, Z is a aryl group or substituted aryl group, Ar₃ is selected from the group consisting of: 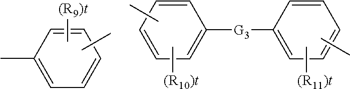
where m=1 or 2, t=1 to 3, R₉, R₁₀, R₁₁ are selected from the group c consisting of hydrogen, halogen, alkyl, substituted alkyl, alkoxy, substituted alkoxy, aryl, substituted aryl, alkyl ester, and substituted alkyl esters, and combinations thereof, G₃ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group.

4. The solution according to claim 1, wherein the carboxylic acid containing repeat unit is formed by reacting 4,4′-diaminodiphenic acid or 3,5-diaminobenzoic acid with at least one aromatic diacid dichloride.

5. The solution according to claim 3, wherein X is the molar fraction of the repeat structure (I), wherein X is from 70% to 99%, and Y is the molar fraction of the repeat structure (II), wherein Y is from 1% to 30%.

6. The solution according to claim 3, wherein the copolymer contains multiple repeat units with structures (I) and (II) where Ar₁, Ar₂, and Ar₃ are the same or different.

7. The solution according to claim 1, wherein at least one repeat unit is formed by reacting an aromatic diamine selected from the group consisting of 4,4′-diamino-2,2′-bistrifluoromethylbenzidine, 9,9-bis(4-aminophenyl) fluorene, 9,9-bis(3-fluoro-4-aminophenyl) fluorene, 4,4′-diamino-2,2′-bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl with at least one aromatic diacid dichloride.

8. The solution according to claim 1, wherein the solvent is methanol, ethanol, propanol, isopropanol (IPA), butanol, acetone, methyl ethyl ketone (MEK), methyl isobutyl ketone (MIBK), toluene, cresol, N,N-dimethylacetamide (DMAc), N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), or N,N-dimethylformamide (DMF), or a mixed solvent comprising at least one of cresol, N,N-dimethylacetamide (DMAc), N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), or N,N-dimethylformamide (DMF), a combination thereof, or a mixed solvent comprising at least one of polar solvent thereof.

9. The solution of according to claim 4, wherein the at least one aromatic diacid dichloride is selected from the group consisting of terephthaloyl dichloride, isophthaloyl dichloride, 2,6-naphthaloyl dichloride, and 4,4,-biphenyldicarbonyl dichloride.

10. The solution according to claim 1, wherein one or both of the terminal —COOH group and terminal —NH₂ group of the aromatic polyamide are end-capped.

11. The solution according to claim 1 for use in the process for manufacturing a display element, an optical element or an illumination element, comprising:
a) applying a solution of an aromatic copolyamide onto a base;
b) forming a polyamide film on the base after the applying step (a); and
c) forming the display element, the optical element or the illumination element on the surface of polyamide film.

12. A process for manufacturing a solution of an aromatic copolyamide, comprising:
a) forming a mixture of two or more aromatic diamines where at least one of the diamines contains one or more free carboxylic acid groups, such that the amount of carboxylic acid containing diamine is greater than approximately 1 mole percent and less than approximately 30 mole percent of the total diamine mixture;
b) dissolving the aromatic diamine mixture in a solvent;
c) reacting the diamine mixture with at least one aromatic diacid dichloride, wherein hydrochloric acid and a polyamide solution is generated; and
d) eliminating the hydrochloric acid with a reagent.

13. The process according to claim 12, wherein the solvent is a polar solvent or a mixed solvent comprising one or more polar solvents.

14. A process for manufacturing a solution of an aromatic copolyamide, comprising:
reacting a mixture of aromatic diamines with at least one aromatic diacid chloride in a solvent to form a polyamide wherein a carboxyl group is incorporated along the polyamide backbone, wherein at least one of the diamines includes a pendant carboxylic acid group of the general formula (III): 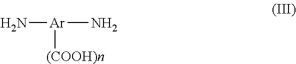
where n=1 to 4, Ar is selected from the group consisting of: 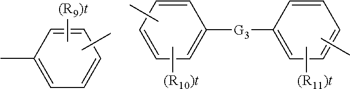
where t=1 to 3, R₉, R₁₀, R₁₁ are selected from the group consisting of hydrogen, halogen, alkyl, substituted alkyl, alkoxy, substituted alkoxy, aryl, substituted aryl, alkyl ester, and substituted alkyl esters, and combinations thereof, G₃ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group.

15. The process according to claim 12, wherein the molar percent of diamine containing the pendent carboxylic acid group is greater than approximately 1 mole percent and less than approximately 30 mole percent of the total diamine mixture.

16. The process according to claim 14, wherein the copolymer contains multiple repeat units with structures (I) and (II) where Ar₁, Ar₂, and Ar₃ are the same or different: 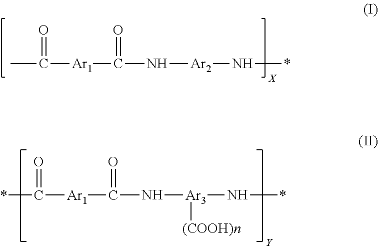
wherein n=1 to 4;
wherein the ratio of X and Y is selected such that the copolyamide is soluble in polar aprotic solvents;
wherein Ar₁ is selected from the group consisting of: 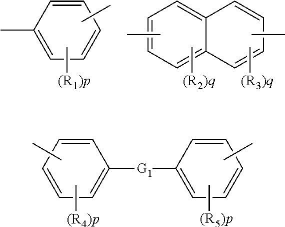
where p=4, q=3, R₁, R₂, R₃, R₄, R₅ are selected from the group consisting of hydrogen, halogen, alkyl, substituted alkyl, alkoxy, substituted alkoxy, aryl, or substituted aryl, alkyl ester and substituted alkyl esters, and combinations thereof, G₁ is selected from a group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, Ar₂ is selected from the group consisting of: 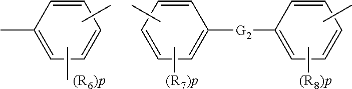
where p=4, R₆, R₇, R₈ are selected from the group consisting of hydrogen, halogen, alkyl, substituted alkyl, alkoxy, substituted alkoxy, aryl, substituted aryl, alkyl ester, and substituted alkyl esters, and combinations thereof, G₂ is selected from a group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, Ar₃ is selected from the group consisting of: 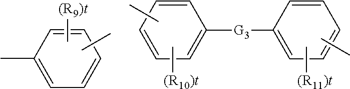
where m=1 or 2, t=1 to 3, R₉, R₁₀, R₁₁ are selected from the group consisting of hydrogen, halogen, alkyl, substituted alkyl, alkoxy, substituted alkoxy, aryl, substituted aryl, alkyl ester, and substituted alkyl esters, and combinations thereof, G₃ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group.

17. The process according to claim 12, wherein the solvent is cresol, N,N-dimethylacetamide (DMAc), N-methyl-2-pyrrolidinone (NMP), dimethylsulfoxide (DMSO), butyl cellosolve, or a mixed solvent comprising at least one of cresol, N,N-dimethylacetamide (DMAc), N-methyl-2-pyrrolidinone (NMP), dimethylsulfoxide (DMSO), butyl cellosolve, methyl cellosolve, ethyl cellosolve, ethyleneglycol monobutylether, propyleneglycol monobuthylether, diethyleneglycol monobutylether, N,N-dimethylacetamide (DMAc), N-methyl-2-pyrrolidone (NMP), dimethylsulfoxide (DMSO), or N,N-dimethylformamide (DMF), a combination thereof, or a mixed solvent comprising at least one of polar solvent thereof.

18. The process according to claim 12, wherein the diamine containing the carboxylic acid group is 4,4′-diaminodiphenic acid or 3,5-diaminobenzoic acid.

19. The process according to claim 12, wherein the aromatic diamine is selected from the group consisting of 4,4′-diamino-2,2′-bistrifluoromethylbenzidine, 9,9-bis(4-aminophenyl) fluorine, and 9,9-bis(3-fluoro-4-aminophenyl)fluorine, 4,4′-diamino-2,2′bistrifluoromethoxylbenzidine, 4,4′-diamino-2,2′-bistrifluoromethyldiphenyl ether, bis-(4-amino-2-trifluoromethylphenyloxyl) benzene, and bis-(4-amino-2-trifluoromethylphenyloxyl) biphenyl.

20. The process according to claim 12, wherein the at least one aromatic diacid dichloride is selected from the group consisting of terephthaloyl dichloride, isophthaloyl dichloride, 2,6-naphthaloyl dichloride, and 4,4,-biphenyldicarbonyl dichloride.

21. The process according to claim 12, wherein the reagent is added to the mixture before or during the reacting step (c).

22. The process according to claim 12, wherein the reaction of the reagent with the hydrochloric acid forms a volatile product.

23. The process according to claim 12, wherein the reagent is organic neutralizing reagent.

24. The process according to claim 12, wherein the reagent is propylene oxide.

25. The process according to claim 12, further comprising the step of end-capping for one or both of the terminal —COOH group and terminal —NH₂ group of the polyamide.

26. The process according to claim 12 wherein the solution of an aromatic copolyamide is produced in the absence of inorganic salt.

27. The process according to claim 12, wherein the solution of an aromatic copolyamide is for use in the process for manufacturing a display element, an optical element or an illumination element, comprising:
a) applying a solution of an aromatic copolyamide onto a base;
b) forming a polyamide film on the base after the applying step (a); and
c) forming the display element, the optical element or the illumination element on the surface of polyamide film.

28. A process for manufacturing a display element, an optical element or an illumination element, comprising:
a) forming a mixture of two or more aromatic diamines where at least one of the diamines contains one or more free carboxylic acid groups, such that the amount of carboxylic acid containing diamine is greater than approximately 1 mole percent and less than approximately 30 mole percent of the total diamine mixture;
b) dissolving the aromatic diamine mixture in a solvent;
c) reacting the diamine mixture with at least one aromatic diacid dichloride, wherein hydrochloric acid and a polyamide solution is generated;
d) eliminating the hydrochloric acid with a reagent to obtain an aromatic copolyamide solution;
e) applying a solution of an aromatic copolyamide onto a base;
f) forming a polyamide film on the base after the applying step (e); and
g) forming the display element, the optical element or the illumination element on the surface of the polyamide film.

29. The process according to claim 28, wherein the solvent is a polar solvent or a mixed solvent comprising one or more polar solvents.

30. A process for manufacturing a display element, an optical element or an illumination element, comprising:
A) applying a solution of an aromatic copolyamide onto a base;
B) forming a polyamide film on the base after the applying step (a); and
C) forming the display element, the optical element or the illumination element on the surface of polyamide film,
wherein the solution of an aromatic copolyamide comprising an aromatic copolyamide and a solvent,
wherein the aromatic copolyamide comprises at least two repeat units of general formulas (I) and (II): 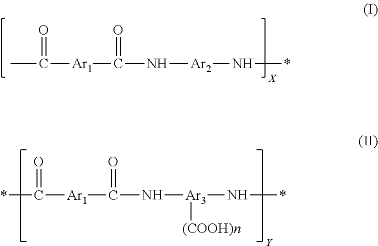
where n=1 to 4, Ar₁ is selected from the group consisting of: 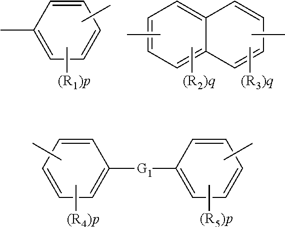
where p=4, q=3, R₁, R₂, R₃, R₄, R₅ are selected from the group consisting of hydrogen, halogen, alkyl, substituted alkyl, alkoxy, substituted alkoxy, aryl, or substituted aryl, alkyl ester and substituted alkyl esters, and combinations thereof; where G₁ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, Ar₂ is selected from the group consisting of: 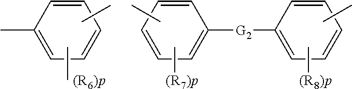
where p=4, R₆, R₇, R₈ are selected from the group consisting of hydrogen, halogen, alkyl, substituted alkyl, alkoxy, substituted alkoxy, aryl, substituted aryl, alkyl ester, and substituted alkyl esters, and combinations thereof; where G₂ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group, wherein Ar₃ is selected from the group consisting of: 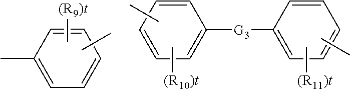
wherein t=1 to 3, R₉, R₁₀, R₁₁ are selected from the group consisting of hydrogen, halogen, alkyl, substituted alkyl, alkoxy, substituted alkoxy, aryl, substituted aryl, alkyl ester, and substituted alkyl esters, and combinations thereof; where G₃ is selected from the group consisting of a covalent bond, a CH₂ group, a C(CH₃)₂ group, a C(CF₃)₂ group, a C(CX₃)₂ group, where X is a halogen, a CO group, an O atom, a S atom, a SO₂ group, a Si (CH₃)₂ group, 9,9-fluorene group, substituted 9,9-fluorene, and an OZO group, where Z is a aryl group or substituted aryl group.

31. The process according to claim 30, wherein X is the molar fraction of the repeat structure (I), wherein X is from 70% to 99%, and Y is the molar fraction of the repeat structure (II), wherein Y is from 1% to 30%.

32. The process according to claim 30, wherein the copolymer contains multiple repeat units with structures (I) and (II) where Ar₁, Ar₂, and Ar₃ are the same or different.

33. The process according to claim 28, further comprising a step of curing the film during and/or after the step (f), wherein the film curing temperature is held at least approximately 280° C. and/or between approximately 90% and approximately 110% of the glass transition temperature of the film for at least approximately 3 minutes.

34. The process according to claim 28, further comprising:
h) de-bonding, from the base, the display element, the optical element or the illumination element formed on the base.
